(19) United States
(12) Patent Application Publication
(10) Pub. No.: US 2020/0002807 A1
(43) Pub. Date: Jan. 2, 2020

(54) VACUUM PROCESSING APPARATUS

(71) Applicant: ULVAC, INC., Kanagawa (JP)

(72) Inventors: Junsuke MATSUZAKI, Kanagawa (JP); Hirohisa TAKAHASHI, Kanagawa (JP); Yuu MIZUSHIMA, Kanagawa (JP)

(73) Assignee: ULVAC, INC., Kanagawa (JP)

(21) Appl. No.: 16/489,589

(22) PCT Filed: Jun. 13, 2018
(86) PCT No.: PCT/JP2018/022529

§ 371 Date: Aug. 28, 2019

(30) Foreign Application Priority Data
Jun. 14, 2017 (JP) 2017-117080

(51) Int. Cl. C23C 14/56; C23C 14/34; C23C 14/50; H01L 21/673; H01L 21/677; B65G 17/30

(52) U.S. Cl. CPC C23C 14/56; C23C 14/34; C23C 14/50; B65G 17/30; H01L 21/67706; H01L 21/67715; H01L 21/6776; H01L 21/673

(57) ABSTRACT

A vacuum processing apparatus, including: a vacuum chamber in which a single vacuum environment is formed; first and a second processing regions provided in the vacuum chamber for performing predetermined vacuum processing on a substrate held by a substrate holder of a plurality of substrate holders; a conveying path for conveying the substrate holder, the conveying path being formed such that a projection shape with respect to a vertical plane forms a continuous ring shape; and a substrate holder conveying mechanism configured to convey the plurality of substrate holders each having a first and a second driven part along the conveying path.

### BACKGROUND

The present disclosure generally relates to a technology of a vacuum processing apparatus that performs vacuum processing, such as, continuous film formation on both surfaces of a substrate held on a substrate holder in a vacuum environment.

Conventionally, there has been known a vacuum processing apparatus that places a plurality of substrates to be film-formed on a substrate holder, such as, a tray, and performs vacuum processing such as continuous film formation.

As such a vacuum processing apparatus, a substrate to be processed is introduced (loaded) into a vacuum chamber and held on a substrate holder, the processed substrate is removed from the substrate holder and discharged (unloaded) outside the vacuum chamber.

In the configuration of a conventional technique, the processing surface of the substrate is maintained horizontally from the loading position to the unloading position, and each process is performed while the substrate moves along the annular conveying path formed in the horizontal plane.

As a result, such a conventional technique has a problem that it is inevitable to increase the size and complexity of a film forming apparatus.

Particularly, in the apparatus which performs processing on both sides of the substrate, the problem discussed above becomes more serious, and there is a problem that it is difficult to improve the throughput.

### SUMMARY

An exemplary aspect of the disclosure provides in a passage type vacuum processing apparatus using a plurality of substrate holders, a technique capable of efficiently performing processing such as, film forming on both surfaces of the substrate, and capable of achieving downsizing of the apparatus and simplification of the configuration.

According to an exemplary aspect of the embodiment, there is provided a vacuum processing apparatus, that includes a vacuum chamber in which a single vacuum environment is formed, first and a second processing regions provided in the vacuum chamber for performing predetermined vacuum processing on a substrate held by a substrate holder of a plurality of substrate holders, a conveying path for conveying the substrate holder, the conveying path being formed such that a projection shape with respect to a vertical plane forms a continuous ring shape and a substrate holder conveying mechanism configured to convey the plurality of substrate holders each having a first and a second driven part along the conveying path, wherein the conveying path includes a first conveying part that conveys the substrate holder in a horizontal state along the conveying path in a first conveying direction, a second conveying part that conveys the substrate holder in a horizontal state along the conveying path in a second conveying direction opposite to the first conveying direction and discharges the substrate holder, a conveying and reversing part that reverses and conveys the substrate holder from the first conveying part toward the second conveying part, and the conveying path is configured such that the first conveying part passes through one of the first and second processing regions, and the second conveying part passes through the other of the first and second processing regions, wherein the substrate holder conveying mechanism includes a plurality of first drive parts each being in contact with the first driven part of the substrate holder, and driving the substrate holder along the conveying path, wherein a direction changing mechanism is provided in a vicinity of the conveying and reversing part of the conveying path, that includes a plurality of second drive parts each being in contact with the second driven part of the substrate holder and driving the substrate holder in the first and second conveying directions, and first and a second direction changing paths for respectively guiding and conveying the first and second driven parts of the substrate holder so as to change a direction of the substrate holder from the first conveying direction to the second conveying direction, and wherein the conveying path is configured such that the first drive parts of the substrate holder conveying mechanism and the second drive parts of the direction changing mechanism are made to operate in synchronization with each other, and the first and second driven parts of the substrate holder are respectively guided and conveyed along the first and second direction changing paths of the direction changing mechanism, and thereby, the substrate holder is delivered from the first conveying part to the second conveying part of the conveying path while a relationship between upper and lower portions of the substrate holder is maintained.

The present embodiment provides the vacuum processing apparatus, wherein each of the first direction changing path and the second direction changing path is formed in an equivalent curved shape that is convex toward the first conveying direction.

The present embodiment provides the vacuum processing apparatus, wherein each of the first direction changing path and the second direction changing path is provided by arranging a pair of guide members close to each other so as to be opposed to each other with a gap slightly larger than a diameter of a first driven part of the substrate holder.

The present embodiment provides the vacuum processing apparatus, wherein the first and second driven parts of the substrate holder are provided so as to extend in a direction orthogonal to the first and second conveying directions, and lengths of the first and second driven parts are different from each other.

The present embodiment provides the vacuum processing apparatus, wherein the direction changing mechanism is disposed at a position outside the substrate holder conveying mechanism with respect to the first and second conveying directions.

The present embodiment provides the vacuum processing apparatus, wherein in the first and second processing regions, film formation is performed in a vacuum environment.

The present embodiment provides the vacuum processing apparatus, wherein the substrate holder is configured to hold a plurality of substrates to be film formed apposed in a direction orthogonal to the first and second conveying directions.

In the present embodiment, in a vacuum chamber in which a single vacuum environment is formed, because the conveying path is formed such that a projection shape with respect to the vertical plane is a continuous ring shapes and includes a substrate holder conveying mechanism that conveys a plurality of substrate holders along the conveying path, it is possible to greatly reduce the space occupied by the conveying path as compared with the conventional art, thereby achieving a large space saving of the apparatus, and thus it is possible to provide a compact vacuum processing apparatus having a simple configuration.

Furthermore, the conveying path of the present embodiment is configured such that a first conveying part for conveying the introduced substrate holder in a horizontal state along the conveying path in the first conveying direction passes through one of the first and second film formation regions, and a second conveying part for conveying and discharging the substrate holder in a horizontal state along the conveying path in the second conveying direction opposite to the first conveying direction passes through the other of the first and second film formation regions. Moreover, the conveying path is configured such that the first drive parts of the substrate holder conveying mechanism and the second drive parts of the direction changing mechanism are made to operate in synchronization with each other, the first and second driven parts of the substrate holder are respectively guided and conveyed along the first and second direction changing paths of the direction changing mechanism, and thereby the substrate holder is delivered from the first conveying part to the second conveying part of the conveying path while the vertical relationship is maintained. According to the present embodiment having such a configuration, it is possible to provide a passage type vacuum processing apparatus capable of efficiently performing processing on both surfaces of a substrate.

On the other hand, in the present embodiment, in a case where the substrate holder is configured to hold a plurality of substrates apposed in a direction orthogonal to the conveying direction, as compared with a case of conveying a substrate holder holding a plurality substrates side by side in the conveying direction of the substrate and performing processing on the substrate as in the prior art, for example, the length of the substrate holder and the surplus space resulting therefrom can be reduced, and therefore, it is possible to achieve further space saving of the vacuum processing apparatus.

### BRIEF DESCRIPTION OF THE DRAWINGS

FIG. 1 is a schematic configuration diagram showing the whole of an embodiment of a vacuum processing apparatus. FIGS. 2(a) and 2(b) show a basic configuration of a substrate holder conveying mechanism and a direction changing mechanism in the present embodiment, wherein FIG. 2(a) is a plan view and FIG. 2(b) is a front view.

FIGS. 3(a) and 3(b) show a configuration of a substrate holder used in the present embodiment, wherein FIG. 3(a) is a plan view and FIG. 3(b) is a front view.

FIGS. 4(a), 4(b), 4(c) and 4(d) show a configuration of a first drive part provided in a conveying drive member of the present embodiment, wherein FIG. 4(a) is a side view as seen from the downstream side in the conveying direction, FIG. 4(b) is a front view, FIG. 4(c) is a side view as seen from the upstream side in the conveying direction, and FIG. 4(d) is a perspective view.

FIG. 5 is a front view showing a configuration of a direction changing mechanism in the present embodiment.

FIG. 6 is an explanatory diagram showing an operation of the vacuum processing apparatus of the present embodiment (part 1).

FIG. 7 is an explanatory diagram showing an operation of the vacuum processing apparatus of the present embodiment (part 2).

FIG. 8 is an explanatory diagram showing an operation of the vacuum processing apparatus of the present embodiment (part 3).

FIGS. 9(a) and 9(b) are explanatory diagrams showing an operation of the vacuum processing apparatus of the present embodiment (part 4).

FIGS. 10(a), 10(b) and 10(c) are explanatory diagrams showing an operation of the substrate holder conveying mechanism and the direction changing mechanism in the present embodiment (part 1).

FIGS. 11(a), 11(b) and 11(c) are explanatory diagrams showing an operation of the substrate holder conveying mechanism and the direction changing mechanism in the present embodiment (part 2).

FIGS. 12(a) and 12(b) are explanatory diagrams showing an operation of the vacuum processing apparatus of the present embodiment (part 5).

FIGS. 13(a), 13(b), 13(c) and 13(d) are explanatory diagrams showing an operation of releasing the contact between the first drive part of the conveying drive member and a first driven shaft of the substrate holder in the present embodiment.

FIG. 14 is an explanatory diagram showing an operation of the vacuum processing apparatus of the present embodiment (part 6).

FIG. 15 is an explanatory diagram showing an operation of the vacuum processing apparatus of the present embodiment (part 7).

FIG. 16 is an explanatory diagram showing an operation of the vacuum processing apparatus of the present embodiment (part 8).

FIG. 17 is s front view showing a modified example of the direction changing mechanism in the present embodiment.

### DETAILED DESCRIPTION OF EMBODIMENTS

Hereinafter, embodiments will be discussed in detail with reference to the drawings.

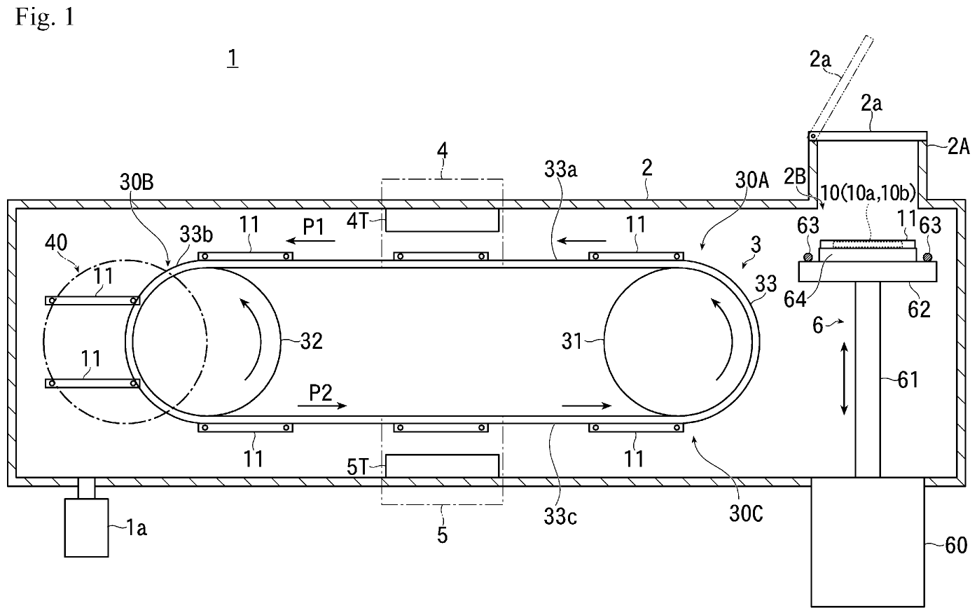

FIG. 1 is a schematic configuration diagram showing the whole of an embodiment of a vacuum processing apparatus according to the present embodiment.

FIGS. 2(a) and 2(b) show the basic configuration of a substrate holder conveying mechanism and a direction changing mechanism in the present embodiment, wherein FIG. 2(a) is a plan view and FIG. 2(b) is a front view.

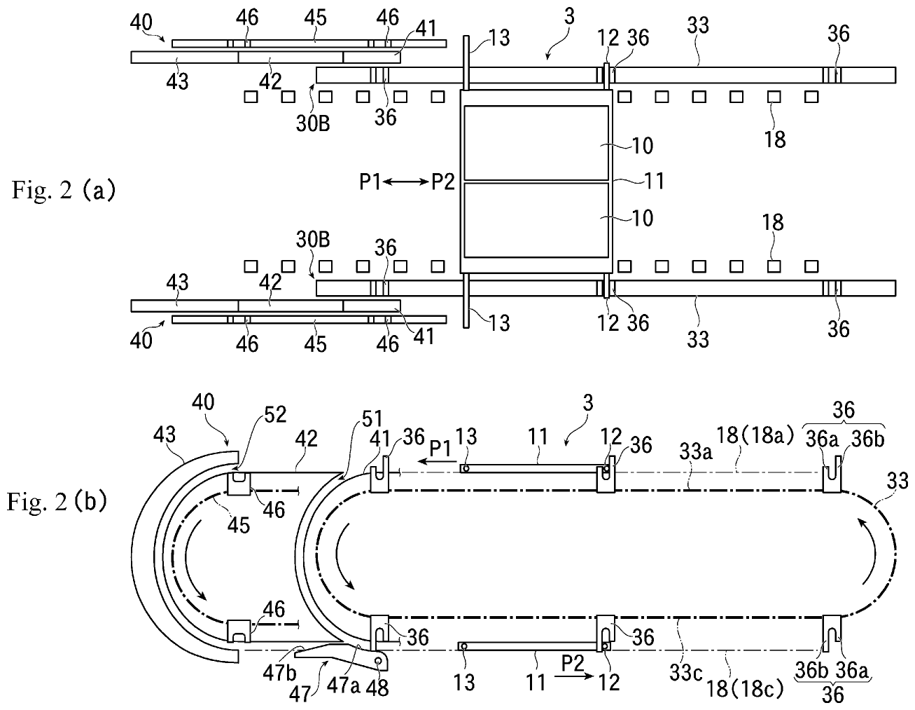

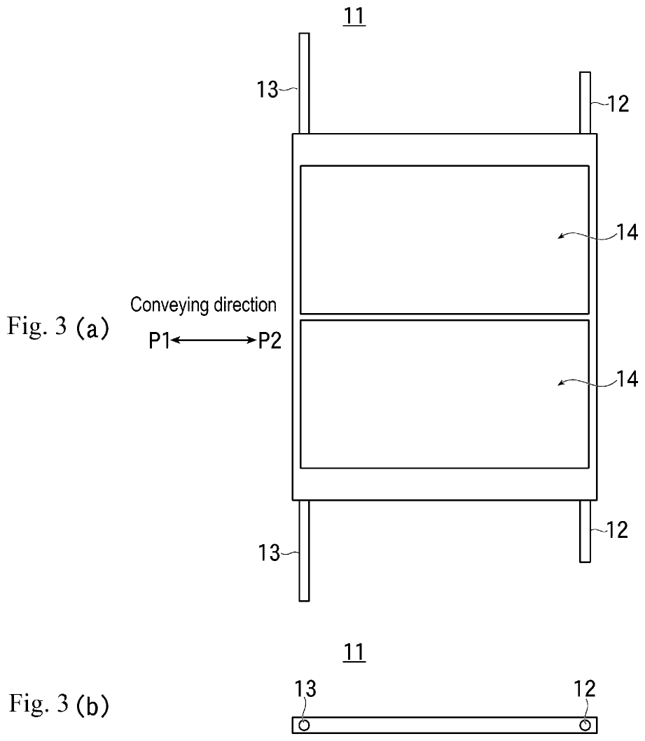

FIGS. 3(a) and 3(b) show the configuration of the substrate holder used in the present embodiment, wherein FIG. 3(a) is a plan view and FIG. 3(b) is a front view.

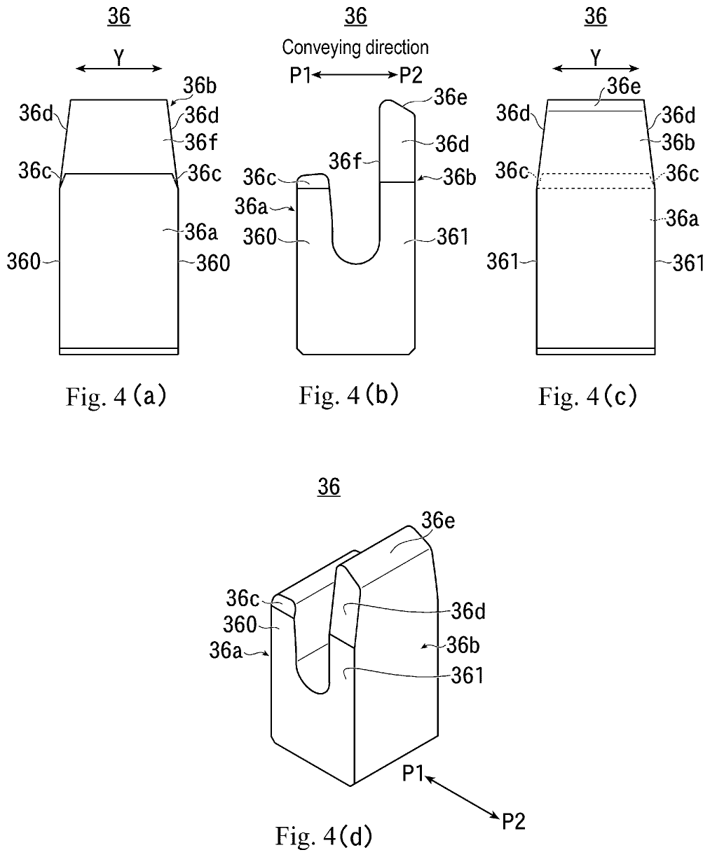

FIGS. 4(a), 4(b), 4(c) and 4(d) show the configuration of a first drive part provided in a conveying drive member of the present embodiment, wherein FIG. 4(a) is a side view as seen from the downstream side in the conveying direction, FIG. 4(b) is a front view, FIG. 4(c) is a side view as seen from the upstream side in the conveying direction, and FIG. 4(d) is a perspective view.

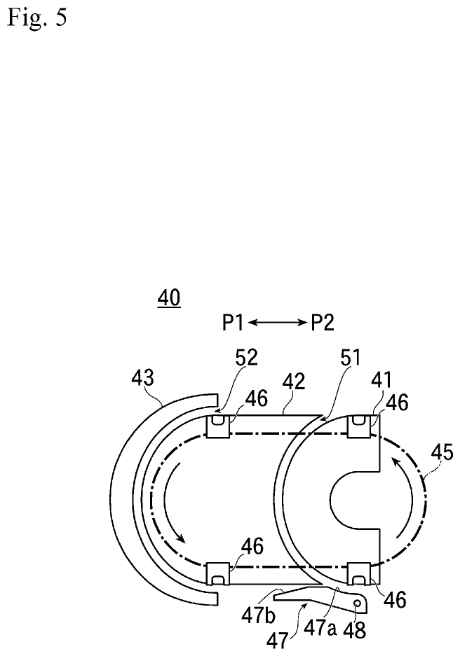

Furthermore, FIG. 5 is a front view showing the configuration of the direction changing mechanism in the present embodiment.

As shown in FIG. 1, a vacuum processing apparatus 1 of the present embodiment has a vacuum chamber 2 connected to a vacuum evacuation apparatus 1a, and having a single vacuum environment formed therein.

Inside the vacuum chamber 2, there is provided a substrate holder conveying mechanism 3 for conveying a substrate holder 11 (discussed later) along a conveying path.

The substrate holder conveying mechanism 3 is configured to continuously convey a plurality of substrate holders 11 that hold the substrate 10.

Here, the substrate holder conveying mechanism 3 has circular first and second drive wheels 31 and 32 having the same diameter, each of which is made of, for example, a sprocket or the like, and operates by a rotational driving force transmitted from a drive mechanism (not shown), and these first and second drive wheels 31, 32 are arranged with a predetermined distance therebetween in a state where their respective rotational axes are parallel.

A continuous conveying drive members 33 made of, for example, a chain or the like is laid across the first and second drive wheels 31, 32.

Furthermore, structure bodies each having the conveying drive member 33 laid across the first and second drive wheels 31, 32 are arranged in parallel at a predetermined distance (see FIG. 2(a)), and the pair of conveying drive members 33 form a continuous ring conveying paths with respect to the vertical plane.

In the present embodiment, a forward-path side conveying part (first conveying part) 33a that moves from the first drive wheel 31 toward the second drive wheel 32 to convey the substrate holder 11 in a first conveying direction P1 is formed in the upper portion of the conveying drive member 33 forming the conveying path, and a reversing part 33b that reverses and turns the conveying direction of the substrate holder 11 into the opposite direction by the conveying drive member 33 in the periphery of the second drive wheel 32 is formed, and furthermore, a return-path side conveying part (second conveying part) 33c that moves from the second drive wheel 32 toward the first drive wheel 31 to convey the substrate holder 11 in a second conveying direction P2 is formed in the lower portion of the conveying drive member 33.

The substrate holder conveying mechanism 3 of the present embodiment is configured such that the forward-path side conveying part 33a located in the upper portion of each conveying drive member 33 and the return-path side conveying part 33c located in the lower portion of each conveying drive member 33 face each other, and overlap in the vertical direction.

The substrate holder conveying mechanism 3 is provided with a substrate holder introducing part 30A for introducing the substrate holder 11, a conveying and reversing part 30B for reversing and conveying the substrate holder 11, and a substrate holder discharging part 30C for discharging the substrate holder 11.

Here, in the vicinity of the conveying and reversing part 30B, a direction changing mechanism 40 to be discussed later is provided.

A first and a second processing region 4 and 5 are provided in the vacuum chamber 2.

In this embodiment, in the vacuum chamber 2, a first processing region 4 having, for example, a sputtering source 4T is provided in the upper portion of the substrate holder conveying mechanism 3, and a second processing region 5 having, for example, a sputtering source 5T is provided in the lower portion of the substrate holder conveying mechanism 3.

In the present embodiment, the forward-path side conveying part 33a of the above-discussed conveying drive member 33 is configured to linearly pass through the first processing region 4 in the horizontal direction, and the return-path side conveying part 33c is configured to linearly pass through the second processing region 5 in the horizontal direction.

Then, when the substrate holder 11 passes through the forward-path side conveying part 33a and the return-path side conveying part 33c of the conveying drive member 33 forming the conveying path, a plurality of substrates 10 (see FIG. 2(a)) held by the substrate holder 11 are conveyed in a horizontal state.

At a position in the vicinity of the substrate holder conveying mechanism 3 in the vacuum chamber 2, for example, at a position adjacent to the first drive wheel 31, there is provided with a substrate carrying-in/out mechanism 6 for delivering and receiving the substrate holder 11 to and from the substrate holder conveying mechanism 3.

The substrate carrying-in/out mechanism 6 of the present embodiment has a supporting part 62 provided at a tip (upper) end portion of a drive rod 61 that is driven, for example, up and down in the vertical direction by an elevating mechanism 60.

In the present embodiment, it is configured such that a transfer robot 64 is provided on the supporting part 62 of the substrate carrying-in/out mechanism 6, the substrate holder 11 is supported on the transfer robot 64 and the substrate holder 11 is moved up and down in the vertical direction, and the substrate holder 11 is delivered and received to and from the substrate holder conveying mechanism 3 by the transfer robot 64.

In this case, as will be discussed later, it is configured such that the substrate holder 11 is delivered from the substrate carrying-in/out mechanism 6 to the substrate holder introducing part 30A of the forward-path side conveying part 33a of the substrate holder conveying mechanism 3 (this position is referred to as “substrate holder delivery position”) and the substrate holder 11 is taken out from the substrate holder discharging part 30C of the return-path side conveying part 33c of the substrate holder conveying mechanism 3 (this position is referred to as “substrate holder takeout position”).

At an upper part of a vacuum chamber 2 in a position, for example, there is provided a substrate carrying-in/out chamber 2A for carrying the substrate 10 into the vacuum chamber 2 and carrying out the substrate 10 from the vacuum chamber 2.

The substrate carrying-in/out chamber 2A is provided, for example, above the supporting part 62 of the substrate carrying-in/out mechanism 6 via a communication opening 2B. For example, in the upper portion of the substrate carrying-in/out chamber 2A, an openable/closeable lid part 2a is provided.

As will be discussed later, it is configured such that an unprocessed substrate 10a carried into the substrate carrying-in/out chamber 2A is delivered to and held by the substrate holder 11 on the transfer robot 64 of the supporting part 62 of the substrate carrying-in/out mechanism 6, and a processed substrate 10b is carried out from the substrate holder 11 on the transfer robot 64 of the supporting part 62 of the substrate carrying-in/out mechanism 6, into the atmosphere outside the vacuum chamber 2, for example.

In the case of the present embodiment, in order to isolate the environment in the vacuum chamber 2 from the substrate carrying-in/out chamber 2A when the substrate 10 is carried in and carried out, for example, a seal member 63, such as an O ring, is provided at the upper edge of the supporting part 62 of the substrate carrying-in/out mechanism 6.

In this case, it is configured such that the supporting part 62 of the substrate carrying-in/out mechanism 6 is raised toward the substrate carrying-in/out chamber 2A, and the seal member 63 on the supporting part 62 is brought into close contact with the inner wall of the vacuum chamber 2 to close the communication opening 2B, thereby, the environment in the substrate carrying-in/out chamber 2A is isolated from the environment in the vacuum chamber 2.

As shown in FIGS. 2(a) and 2(b), a plurality of first drive parts 36 are provided so as to project outwardly of the conveying drive member 33, at predetermined intervals in each of the pair of conveying drive members 33 of the substrate holder conveying mechanism 3 of the present embodiment.

For example, as shown in FIG. 2(b), the first drive part 36 is formed in a J hook shape (a shape formed with a groove portion in which the height of a first protrusion portion 36a on the downstream side in the conveying direction is lower than the height of a second protrusion portion 36b on the upstream side in the conveying direction), and is configured to contact a first driven shaft 12 (to be discussed later) of the substrate holder 11 supported by a substrate holder supporting mechanism 18 (to be discussed below) and drive the substrate holder 11 in the first or second conveying direction P1 or P2.

A pair of the substrate holder supporting mechanisms 18 for supporting the substrate holder 11 to be conveyed are provided inside the pair of conveying drive members 33.

Each of the substrate holder supporting mechanisms 18 is made of a rotatable member, such as, a plurality of rollers, for example, and is provided in the vicinity of the conveying drive member 33.

In the present embodiment, a forward-path side substrate holder supporting mechanism 18a is provided in the vicinity above the forward-path side conveying part 33a of the conveying drive member 33 and a return-path side substrate holder supporting mechanism 18c is provided in the vicinity below the return-path side conveying part 33c of the conveying drive member 33, and they are arranged and configured so as to support both edge portions of the lower surface of the substrate holder 11 to be conveyed.

Furthermore, the forward-path side substrate holder supporting mechanism 18a is provided up to the vicinity of an entry port of a first direction changing path 51 of the direction changing mechanism 40 to be discussed later, and the return-path side substrate holder supporting mechanism 18c is provided up to the vicinity of a discharge port of a second direction changing path 52 of the direction changing mechanism 40 to be discussed later.

The substrate holder 11 used in the present embodiment is for performing vacuum processing on both surfaces of the substrate 10 and is made of a tray shape having an opening.

As shown in FIGS. 2(a) and 3(a), the substrate holder 11 of the present embodiment is formed in, for example, a long rectangular flat-plate shape, and in its longitudinal direction, that is, in a direction orthogonal to the first and second conveying directions P1 and P2, there are provided a plurality of holding parts 14 for arranging and holding, for example, a plurality of rectangular substrates 10 in a row, respectively.

Here, each holding part 14 is provided with, for example, a rectangular opening which has the same size and shape as each substrate 10, and from which both surfaces of each substrate 10 are entirely exposed, and is configured to hold each substrate 10 by a holding member (not shown).

In the present disclosure, although not particularly limited, from the viewpoint of reducing the installation area and improving the processing capability, it is preferable that the substrate holder 11 arrange and hold a plurality of substrates 10 in a row, respectively, in the direction orthogonal to the conveying direction, as in the present embodiment.

However, from the viewpoint of improving processing efficiency, it is also possible to arrange a plurality of substrates 10 in a plurality of rows in a direction orthogonal to the conveying direction.

On the other hand, a first driven shaft (a first driven part) 12 is provided at each end portion in the longitudinal direction of the substrate holder 11 on the upstream side end in the first conveying direction P1, and a second driven shaft (a second driven part) 13 is provided at each end portion on the downstream side in the first conveying direction P1.

Each of the first and second driven shafts 12 and 13 is formed to have a circular cross section shape centering on a rotational axis extending in a direction orthogonal to the longitudinal direction of the substrate holder 11, that is, the first and second conveying directions P1 and P2, (See FIGS. 3(a) and 3(b)).

In the present embodiment, the dimensions of the second driven shaft 13 are determined such that the length of the second driven shaft 13 is longer than the length of the first driven shaft 12.

More specifically, as shown in FIG. 2(a), the dimensions of the first and second driven shafts 12 and 13 are determined such that when the substrate holder 11 is disposed in the substrate holder conveying mechanism 3, the first driven shafts 12 on both side of the substrate holder 11 contact the first drive parts 36 of the substrate holder conveying mechanisms 3, and when the substrate holder 11 is disposed in the direction changing mechanism 40 to be discussed later, the second driven shaft 13 contacts the second drive part 46 to be discussed later.

On the downstream side of the pair of conveying drive members 33 in the first conveying direction P1, a pair of direction changing mechanisms 40 having the same configuration is provided.

In the case of the present embodiment, the pair of direction changing mechanisms 40 are arranged outside the pair of conveying drive members 33 with respect to the first and second conveying directions P1 and P2, respectively.

Each of the pair of direction changing mechanisms 40 is provided such that the upstream side portion in the first conveying direction P1 slightly overlaps the downstream side portion of each conveying drive member 33 in the first conveying direction P1.

As shown in FIG. 2(b) and FIGS. 4(a) to 4(d), in the first drive part 36 provided in the conveying drive member 33 of the present embodiment, a first tapered portion 36c for performing alignment of the substrate holder 11 in a direction orthogonal to the conveying direction is provided at a portion which is a side portion (a side portion with respect to the conveying direction) formed in a planar shape of the first protrusion portion 36a and at its tip portion (a portion on the outer side in the conveying direction).

Further, at the side portion (the portion on the side of the conveying direction) formed in the planar shape of the second protrusion portion 36b and at its tip portion (the portion on the outer side in the conveying direction), a second tapered portion 36d for performing alignment of the substrate holder 11 in a direction orthogonal to the conveying direction is provided.

The first and second tapered portions 36c and 36d are formed such that the dimensions of the first and second protrusion portions 36a, 36b in the width direction, that is, the direction orthogonal to the conveying direction become small toward the tip portion, that is, toward the outer side in the conveying direction, respectively.

In the present embodiment, the first and second tapered portions 36c, 36d are provided on both sides of the first protrusion portion 36a and the second protrusion portion 36b on the side with respect to the conveying direction.

In the case of the present disclosure, the dimension of the first tapered portion 36c provided in the first protrusion portion 36a in the first drive part 36 is not particularly limited, but from the viewpoint of ensuring the alignment of the substrate holder 11 in a direction orthogonal to the conveying direction, it is preferable to form the first tapered portions 36c at angles of 10 to 45° with respect to side portions 360 formed in the planar shape of the first protrusion portion 36a, respectively.

In this case, specifically, the lengths of the first tapered portions 36c of the first protrusion portion 36a in the direction toward the outer side in the conveying direction are preferably set to 1 to 3 mm, respectively, and the processing dimensions of the first tapered portions 36c in the direction orthogonal to the conveying direction (the direction indicated by the Y direction in FIGS. 4(a) and 4(c)) are preferably set to 1 to 15 mm, respectively.

Furthermore, the dimension of the second tapered portion 36d provided in the second protrusion portion 36b in the first drive part 36 is not particularly limited, but from the viewpoint of ensuring the alignment of the substrate holder 11 in a direction orthogonal to the conveying direction, it is preferable to form the second tapered portions 36d at angles of 5 to 45° with respect to side portions 361 formed in the planar shape of the second protrusion portion 36b, respectively.

In this case, specifically, the lengths of the second tapered portions 36d of the second protrusion portion 36b in the direction toward the outer side in the conveying direction are preferably set to 1 to 5 mm, respectively, and the processing dimensions of the second tapered portions 36d in the direction orthogonal to the conveying direction (the direction indicated by the Y direction in FIGS. 4(a) and 4(c)) are preferably set to 1 to 50 mm, respectively.

Note that, in the present embodiment, in order to reduce the number of partial points due to commonality of components, the first and second tapered portions 36c and 36d are provided on both side portions of the first and second protrusion portions 36a and 36b. However, the present disclosure is not limited to this, and the first and second tapered portions 36c and 36d can be provided only on the side of the substrate holder 11 (on the inner side portion with respect to the conveying direction) of the side portions of the first and second protrusion portions 36a and 36b.

On the other hand, in the present embodiment, as shown in FIGS. 4(b) to 4(d), a third tapered portion 36e is provided at the tip portion (the end on the outer side in the conveying direction) of the second protrusion portion 36b of the first drive part 36.

The third tapered portion 36e is formed such that a portion on the upstream side in the conveying direction of the tip portion of the second protrusion portion 36b is inclined inward in the conveying direction (the portion on the upstream side in the first conveying direction P1 in the example shown in FIGS. 4(b) and 4(d)).

In this case, the third tapered portion 36e is rounded at the edge portions on the upstream side and downstream side in the conveying direction, and its central portion is formed in a planar shape.

In the case of the present embodiment, the dimension of the third tapered portion 36e provided in the second protrusion portion 36b in the first drive part 36 is not particularly limited, but as will be discussed later, from the viewpoint of releasing the contact (engagement) state between the second protrusion portion 36b of the first drive part 36 and the first driven shaft 12 of the substrate holder 11 as soon as possible when the substrate holder 11 is delivered from the substrate holder conveying mechanism 3 to the substrate carrying-in/out mechanism 6, it is preferable to form the third tapered portion 36e at an angle of 45 to 80° with respect to a portion 36f (see FIG. 4(b)) formed in a planar shape of the second protrusion portion 36b on the downstream side in the conveying direction.

As shown in FIG. 5, the direction changing mechanism 40 of the present embodiment has a first guide member 41, a second guide member 42, and a third guide member 43, and these first to third guide members 41 to 43 are arranged in this order from the upstream side in the first conveying direction P1.

In the present embodiment, the first to third guide members 41 to 43 are arranged respectively in the vicinity of the outer sides of the pair of conveying drive members 33, and further, conveying drive members 45, which will be discussed later, are arranged respectively in the vicinity of the outer sides of the first to third guide members 41 to 43.

In FIG. 2(b), a part of the direction changing mechanism 40 is omitted, and the positional relationship between the members in the conveying direction is shown clearly, ignoring the overlapping relationship of the members.

As shown in FIG. 2(a) and FIG. 5, the first to third guide members 41 to 43 are made of, for example, plate-shaped members, and are provided in the vertical direction, respectively.

Here, a portion of the first guide member 41 on the downstream side in the first conveying direction P1 is formed in a curved surface shape that is convex toward the downstream side in the first conveying direction P1, and a portion of the second guide member 42 on the upstream side in the first conveying direction P1 is formed in a curved surface shape that is concave toward the downstream side in the first conveying direction P1.

The first and second guide members 41 and 42 are arranged close to each other such that a portion of the first guide member 41 on the downstream side in the first conveying direction P1 and a portion of the second guide member 42 on the upstream side in the first conveying direction P1 are formed to have the same curved surface shape and these portions face each other having a gap slightly larger than the diameter of the first driven shaft 12 of the substrate holder 11. The first direction changing path 51 for guiding the first driven shaft 12 of the substrate holder 11 is provided by this gap.

A portion of the second guide member 42 on the downstream side in the first conveying direction P1 is formed in a curved surface shape that is convex toward the downstream side in the first conveying direction P1 and a portion of the third guide member 43 on the upstream side in the first conveying direction P1 is formed in a curved surface shape that is concave toward the downstream side in the first conveying direction P1.

The second and third guide members 42 and 43 are arranged close to each other such that a portion of the second guide member 42 on the downstream side in the first conveying direction P1 and a portion of the third guide member 43 on the upstream side in the first conveying direction P1 are formed to have the same curved surface shape and these portions face each other with a gap slightly larger than the diameter of the second driven shaft 13 of the substrate holder 11. Then, the second direction changing path 52 for guiding the second driven shaft 13 of the substrate holder 11 by this gap is provided.

In the present embodiment, a portion of the second guide member 42 on the downstream in the first conveying direction P1 is formed in a curved surface shape equivalent to the portion of the first guide member 41 on the downstream side in the first conveying direction P1, and further a portion of the third guide member 43 on the upstream side in the first conveying direction P1 is formed in a curved surface shape equivalent to the portion of the second guide member 42 on the upstream side in the first conveying direction P1.

With such a configuration, the first direction changing path 51 and the second direction changing path 52 are formed in the same curved surface shape.

Furthermore, in the present embodiment, the dimensions of the first and second direction changing paths 51 and 52 are determined such that the distance in the horizontal direction of each portion of the first and second direction changing paths 51 and 52 is set to be equivalent to the distance between the first and second driven shafts 12 and 13 of the substrate holder 11.

Further, in the present embodiment, the upper side opening of the first direction changing path 51 is the entry port of the first driven shaft 12 of the substrate holder 11, and the opening is configured such that its height position is lower than a height position of the second driven shaft 13 of the substrate holder 11 supported by the forward-path side substrate holder supporting mechanism 18a (see FIG. 2(b)).

Furthermore, the lower opening of the first direction changing path 51 is the discharge port of the first driven shaft 12 of the substrate holder 11, and the opening is configured such that its height position is higher than a height position of the second driven shaft 13 of the substrate holder 11 supported by the return-path side substrate holder supporting mechanism 18c (see FIG. 2(b)).

Regarding to the second direction changing path 52, the upper opening thereof is the entry port of the second driven shaft 13 of the substrate holder 11, and the opening is configured such that its height position is equivalent to a height position of the second driven shaft 13 of the substrate holder 11 supported by the forward-path side substrate holder supporting mechanism 18a (see FIG. 2(b)).

On the other hand, the lower opening of the second direction changing path 52 is the discharge port of the second driven shaft 13 of the substrate holder 11, and the opening is configured such that its height position is equivalent to a height position of the second driven shaft 13 of the substrate holder 11 supported by the return-path side substrate holder supporting mechanism 18c (see FIG. 2(b)).

The direction changing mechanism 40 of the present embodiment has, for example, a pair of sprockets and a conveying drive member 45 composed of a chain wound around the pair of sprockets, and the conveying drive member 45 is configured to become a continuous ring shapes with respect to the vertical plane.

The conveying drive member 45 is configured such that the curvature radius of the reversing part of the conveying drive member 45 is equivalent to the curvature radius of the reversing part 33b of the conveying drive member 33 of the substrate holder conveying mechanism 3.

In addition, the upper portion of the conveying drive member 45 is driven to move in the first conveying direction P1 and the lower portion thereof is driven to move in the second conveying direction P2.

A plurality of second drive parts 46 are provided on the conveying drive member 45 so as to protrude to the outer side of the conveying drive member 45 at predetermined intervals.

The second drive part 46 is formed with a concave portion in a portion on the outer side of the conveying drive member 45, and is configured such that the edge portion of the concave portion is in contact with the second driven shaft 13 of the substrate holder 11 to support and drive the substrate holder 11 along the second direction changing path 52.

Furthermore, as will be discussed later, in the second drive part 46 of the present embodiment, the path of the conveying drive member 45 and the dimension of the second drive part 46 are set such that when the second drive part 46 reaches the positions of the entry port and discharge port of the second direction changing path 52, end portion of the concave portion side retracts from the second direction changing path 52 (see FIG. 2(b)).

In the present embodiment, as will be discussed later, operations of the conveying drive member 33 of the substrate holder conveying mechanism 3 and the conveying drive member 45 of the direction changing mechanism 40 are controlled so that the second drive part 46 operates in synchronization with the first drive part 36 of the substrate holder conveying mechanism 3.

In the present embodiment, the shapes and dimensions of the first and second drive parts 36 and 46 and the first and second direction changing paths 51 and 52 are set respectively such that when the first drive part 36 of the substrate holder conveying mechanism 3 drives the substrate holder 11 in the first conveying direction P1 to make the first and second driven shafts 12 and 13 enter the first and second direction changing paths 51 and 52, the substrate holder 11 holds the horizontal state and the first and second drive parts 36 and 46 support and move the first and second driven shafts 12 and 13 so as to smoothly discharge the substrate holder 11 from the first and second direction changing paths 51 and 52.

On the other hand, below the first guide member 41 and the second guide member 42, and in the vicinity of the discharge port of the first direction changing path 51, there is provided a delivery member 47 for smoothly delivering the substrate holder 11 from the direction changing mechanism 40 to the return-path side substrate holder supporting mechanism 18c of the substrate holder supporting mechanism 18.

The delivery member 47 is composed of, for example, an elongated member extending in the horizontal direction, and is configured to rotate and move vertically around a rotational axis 48 provided at a position below the return-path side substrate holder supporting mechanism 18c at the end on the side of the second conveying direction P2. The delivery member 47 is added upward force by an elastic member (not shown) at the side of the first conveying direction P1.

On the upper portion of the delivery member 47, in the vicinity of the discharge port of the first direction changing path 51 on the side of the second conveying direction P2, there is provided a delivery part 47a formed in a curved surface shape, so as to be continuous with the first direction changing path 51, and continuous with the return-path side substrate holder supporting mechanism 18c of the substrate holder supporting mechanism 18 (See FIG. 2(b)).

In addition, an inclined surface 47b inclined downward in the first conveying direction P1 is provided on the upper portion of the delivery member 47 at a portion on the side of the first conveying direction P1. The inclined surface 47b is provided at a height position facing the discharge port of the second direction changing path 52.

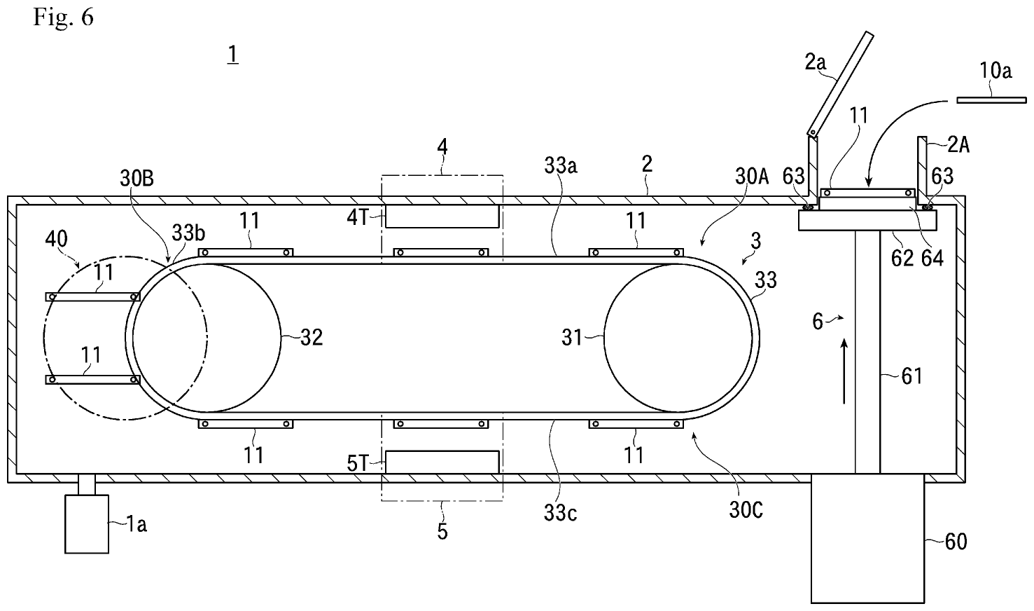

Hereinafter, the operation of the vacuum processing apparatus 1 of the present embodiment will be discussed with reference to FIGS. 6 to 16.

In this embodiment, first, as shown in FIG. 6, in a state in which the seal member 63 on the supporting part 62 of the substrate carrying-in/out mechanism 6 is brought into tight contact with the inner wall of the vacuum chamber 2 to isolate the environment in the substrate carrying-in/out chamber 2A from the environment in the vacuum chamber 2, after venting to the atmospheric pressure, the lid part 2a of the substrate carrying-in/out chamber 2A is opened.

Thereafter, the unprocessed substrate 10a is mounted and held on the substrate holder 11 on the transfer robot 64 of the supporting part 62 of the substrate carrying-in/out mechanism 6 by using a transfer robot (not shown).

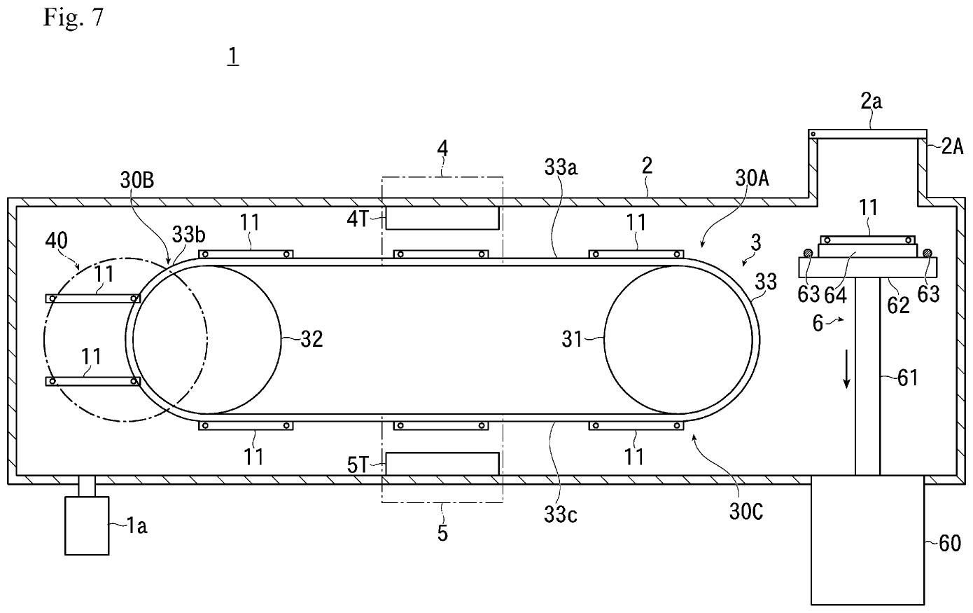

Then, as shown in FIG. 7, after the lid part 2a of the substrate carrying-in/out chamber 2A is closed, and the substrate carrying-in/out chamber 2A is vacuum-evacuated to a predetermined pressure, the supporting part 62 of the substrate carrying-in/out mechanism 6 is lowered to the above-discussed substrate holder delivery position, and the height of the substrate holder 11 is set to the same height position as that of the forward-path side conveying part 33a of the conveying drive member 33.

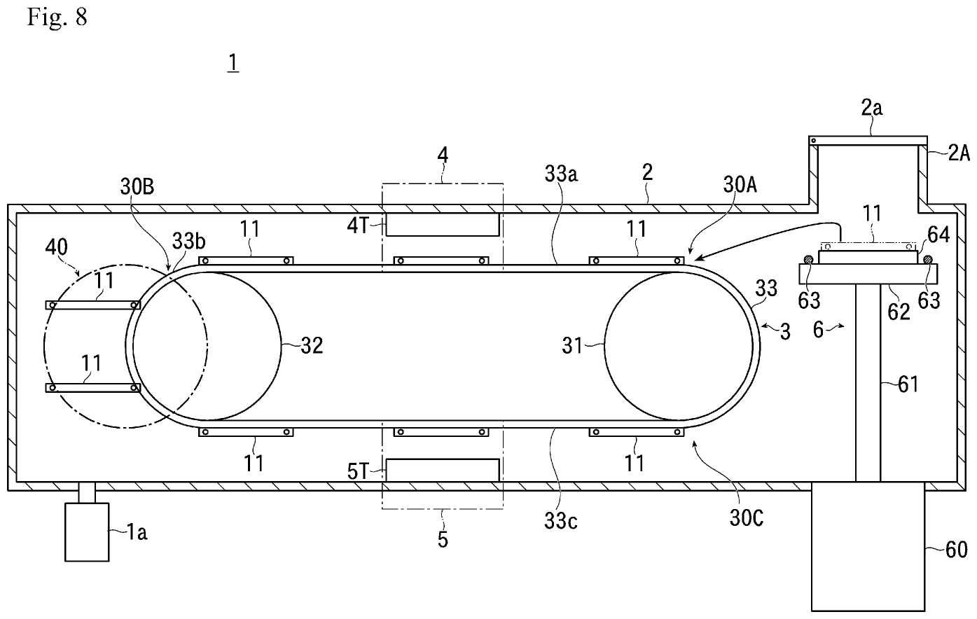

Further, as shown in FIG. 8, the substrate holder 11 is disposed on the substrate holder introducing part 30A of the substrate holder conveying mechanism 3 by the transfer robot 64 provided on the supporting part 62 of the substrate carrying-in/out mechanism 6.

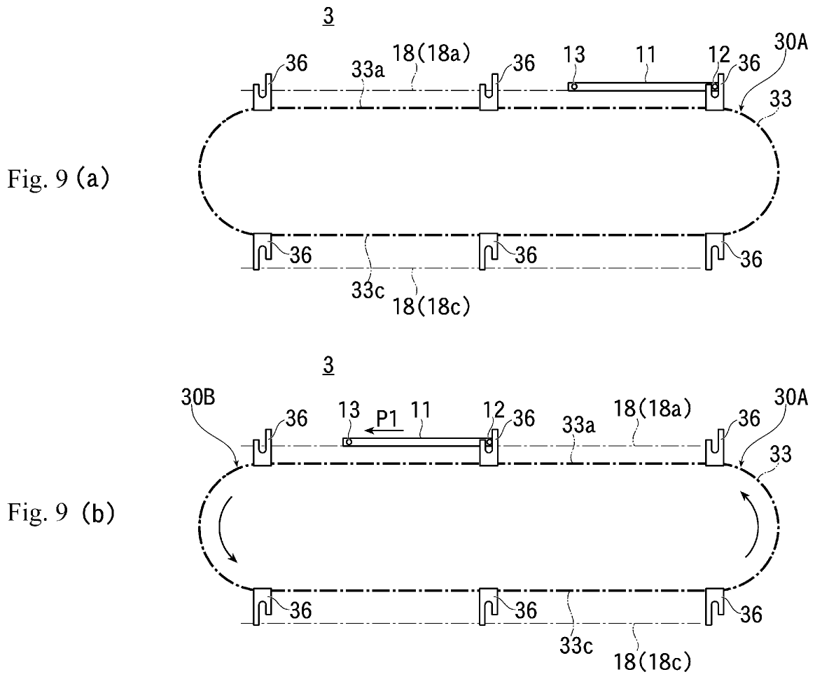

In this case, as shown in FIG. 9(a), the first driven shaft 12 of the substrate holder 11 is positioned so as to be disposed in the groove of the first drive part 36 and placed on the forward-path side substrate holder supporting mechanism 18a.

During this operation, there may be a case where the substrate holder 11 is displaced in a direction orthogonal to the first conveying direction P1 (see FIG. 9(b)) and the edge portion of the substrate holder 11 on the side in a direction orthogonal to the conveying direction comes into contact with the first drive part 36. In the present embodiment, however, as discussed above, the first protrusion portion 36a and the second protrusion portion 36b of the first drive part 36 are provided with the first and second tapered portions 36c and 36d, respectively, and thus, the edge portions of the substrate holder 11 on the side in a direction orthogonal to the conveying direction are in contact with the first and second protrusion portions 36a and 36b of the first drive part 36, so that the substrate holder 11 is aligned in the direction orthogonal to the conveying direction, and the positional displacement is corrected. As a result, the first driven shaft 12 of the substrate holder 11 can be smoothly disposed in the groove portion of the first drive part 36.

Thereafter, in this state, as shown in FIG. 9(b), the forward-path side conveying part 33a of the conveying drive member 33 of the substrate holder conveying mechanism 3 is moved in the first conveying direction P1.

As a result, the first driven shaft 12 of the substrate holder 11 is driven in the first conveying direction P1 by the first drive part 36 on the forward-path side conveying part 33a of the conveying drive member 33, and the substrate holder 11 is conveyed on the forward-path side conveying part 33a of the conveying drive member 33 toward the conveying and reversing part 30B.

In this case, when the substrate holder 11 passes through the position of the first processing region 4 shown in FIG. 8, predetermined vacuum processing (for example, film formation by sputtering) is performed on a first surface of the unprocessed substrate 10a (see FIG. 6) held by the substrate holder 11 on the side of the first processing region 4.

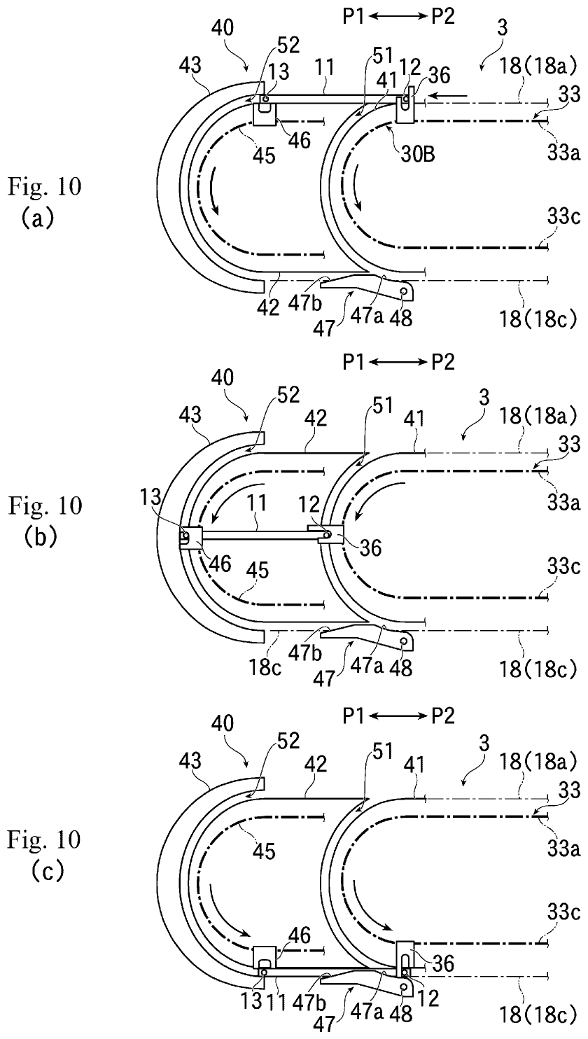

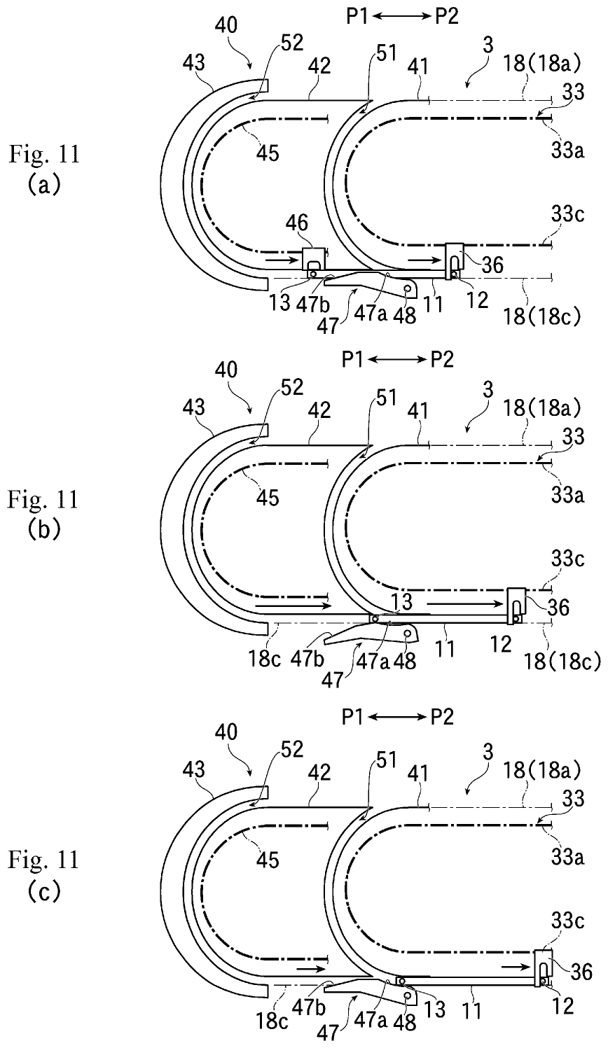

FIGS. 10(a) to 10(c) and FIGS. 11(a) to 11(c) are explanatory diagrams showing the operation of the substrate holder conveying mechanism and the direction changing mechanism in the present embodiment.

In the present embodiment, as shown in FIG. 10(a), by movement of the first drive part 36 of the substrate holder conveying mechanism 3 in the first conveying direction P1, the substrate holder 11 reached the conveying and reversing part 30B of the substrate holder conveying mechanism 3 is further moved in the first conveying direction P1, and the second driven shaft 13 of the substrate holder 11 is disposed at a position of the entry port of the second direction changing path 52 of the direction changing mechanism 40.

In this case, the operation of the conveying drive member 45 is controlled such that the second drive part 46 of the direction changing mechanism 40 is positioned below the second driven shaft 13 of the substrate holder 11.

Then, the conveying drive member 33 of the substrate holder conveying mechanism 3 is driven to move the first drive part 36 in the first conveying direction P1, and the conveying drive member 45 of the direction changing mechanism 40 is driven to move the second drive part 46 in the first conveying direction P1. In this case, control is performed such that the operations of the first drive part 36 and the second drive part 46 are synchronized.

As a result, as shown in FIG. 10(b), the first and second driven shafts 12 and 13 of the substrate holder 11 are supported and driven by the first and second drive parts 36 and 46, respectively, and are moved downward in the first and second direction changing paths 51 and 52, respectively.

In this process, the first driven shafts 12 of the substrate holder 11 make contact with the edge portions of the first guide member 41 or the second guide member 42 in the first direction changing path 51 but do not make contact with both at the same time, and the second driven shafts 13 make contact with the edge portions of the second guide member 42 or the third guide member 43 in the second direction changing path 52 but do not make contact with both at the same time. In this case, a relationship between upper and lower portions of the substrate holder 11 is maintained.

Then, from the vicinity where the first and second driven shafts 12 and 13 have respectively passed through the middle portions of the first and second direction changing paths 51 and 52, the conveying directions of the first and second driven shafts 12 and 13 are respectively turned to the second conveying direction P2 which is the opposite direction of the first conveying direction P1 while the relationship between upper and lower portion of the substrate holder 11 is maintained.

In this process, the first driven shafts 12 of the substrate holder 11 do not make contact at the same time in the first direction changing path 51 but make contact with the edge portions of the first guide member 41 or the second guide member 42, and the second driven shafts 13 do not contact at the same time in the second direction changing path 52 but make contact with the edge portions of the second guide member 42 or the third guide member 43.

Further, when the conveying drive member 33 of the substrate holder conveying mechanism 3 and the conveying drive member 45 of the direction changing mechanism 40 continue to be driven, as shown in FIG. 10(c), the first driven shaft 12 of the substrate holder 11 is disposed at a position above the delivery member 47 via the discharge port of the first direction changing path 51 and the delivery part 47a of the delivery member 47, and the second driven shaft 13 of the substrate holder 11 is disposed at the position of the discharge port of the second direction changing path 52. Thereafter, as shown in FIG. 11(a), the substrate holder 11 is delivered to the return-path side substrate holder supporting mechanism 18c of the substrate holder supporting mechanism 18.

Note that, at the time point shown in FIG. 10(c), the second drive part 46 of the direction changing mechanism 40 and the second driven shaft 13 of the substrate holder 11 are not in contact with each other, and the substrate holder 11 moves in the second conveying direction P2 by driving by contact between the first drive part 36 of the substrate holder conveying mechanism 3 and the first driven shaft 12.

Then, as shown in FIG. 11(b), by further drive of the conveying drive member 33 of the substrate holder conveying mechanism 3, the second driven shaft 13 of the substrate holder 11 is in contact with the inclined surface 47b of the delivery member 47 to rotationally move the delivery member 47 downward, and as shown in FIG. 11(c), the second driven shaft 13 of the substrate holder 11 passes above the delivery member 47, and the substrate holder 11 moves in the second conveying direction P2.

After this process, the delivery member 47 returns to the original position by the adding force of the elastic member (not shown).

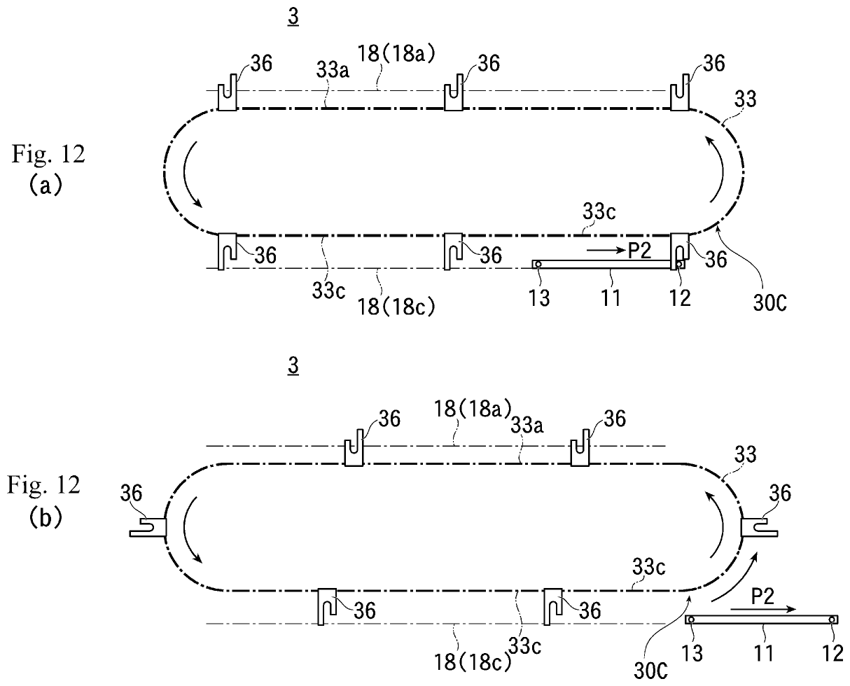

Thereafter, as shown in FIG. 12(a), the return-path side conveying part 33c of the conveying drive member 33 of the substrate holder conveying mechanism 3 is moved in the second conveying direction P2, the first driven shaft 12 is driven in the same direction by the first drive part 36, and thereby the substrate holder 11 is conveyed toward the substrate holder discharging part 30C.

In this case, when the substrate holder 11 passes through the position of the second processing region 5 shown in FIG. 8, predetermined vacuum processing (for example, film formation by sputtering) is performed on a second surface on the side of the second processing region 5 of the unprocessed substrate 10a (see FIG. 6) held by the substrate holder 11.

After the substrate holder 11 has reached the substrate holder discharging part 30C, when the return-path side conveying part 33c of the conveying drive member 33 is moved in the second conveying direction P2, and the first drive part 36 is driven in the same direction as the first drive part 36 is inclined from the vertical direction in accordance with the movement of the return-path side conveying part 33c, as shown in FIG. 12(b), the contact between the first drive part 36 and the first driven shaft 12 is released, whereby the substrate holder 11 loses propulsive force.

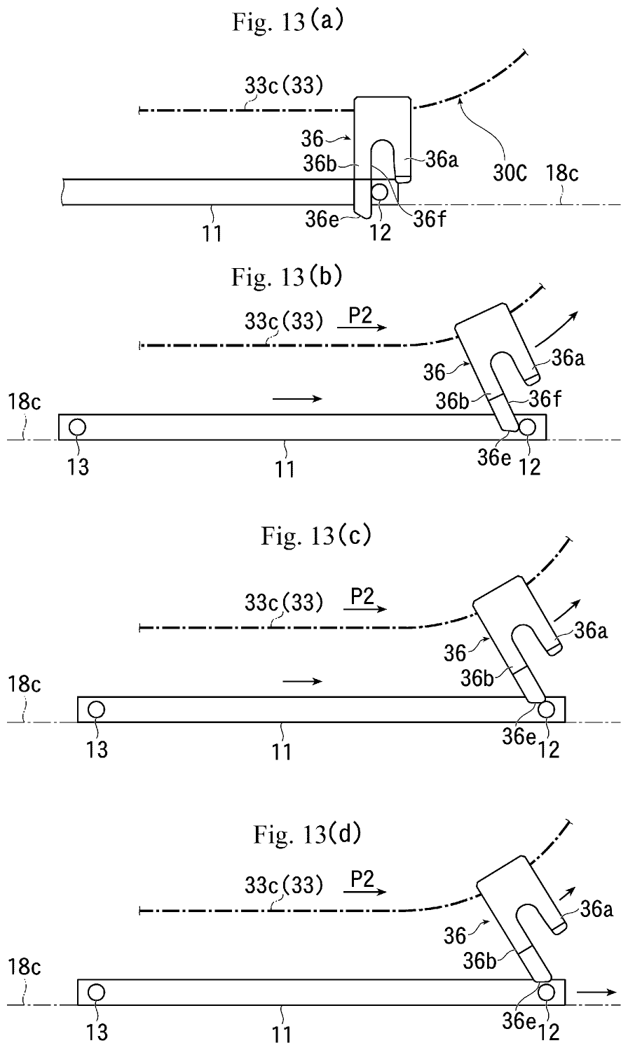

FIGS. 13(a) to 13(d) are explanatory diagrams showing the operation of releasing the contact between the first drive part of the conveying drive member and the first driven shaft of the substrate holder in the present embodiment.

When the substrate holder 11 has reached the substrate holder discharging part 30C, as shown in FIG. 13(a), in a state in which the second protrusion portion 36b of the first drive part 36 is directed in the vertical direction, the portion 36f on the downstream side in the conveying direction is in contact with the first driven shaft 12 of the substrate holder 11.

From this state, when the return-path side conveying part 33c of the conveying drive member 33 is moved in the second conveying direction P2, the substrate holder 11 moves on the return-path side substrate holder supporting mechanism 18c in the second conveying direction P2, as shown in FIG. 13(b), the first drive part 36 moves upward along the first drive wheel 31 (see FIG. 1), and the second protrusion portion 36b is inclined in a direction approaching horizontal, so that the first driven shaft 12 of the substrate holder 11 is in contact with a rounded portion on the downstream side in the conveying direction, at the tip portion of the second protrusion portion 36b of the first drive part 36.

As shown in FIG. 13(c), when the return-path side conveying part 33c of the conveying drive member 33 is continuously moved in the second conveying direction P2, the first drive part 36 moves further upward along the first drive wheel 31, and thereby the tip portion of the second protrusion portion 36b of the first drive part 36 gets over the upper portion of the first driven shaft 12 of the substrate holder 11 while being in contact with the first driven shaft 12.

In the present embodiment, as discussed above, the third tapered portion 36e is formed at the tip portion of the second protrusion portion 36b, such that the tip portion of the second protrusion portion 36b on the upstream side in the conveying direction is inclined inward in the conveying direction, and when the tip portion of the second protrusion portion 36b of the first drive part 36 gets over the upper portion of the first driven shaft 12 of the substrate holder 11, the surface of the third tapered portion 36e becomes substantially horizontal.

Then, from this state, when the return-path side conveying part 33c of the conveying drive member 33 is slightly moved in the second conveying direction P2, as shown in FIG. 13(d), the first drive part 36 having the third tapered portion 36e is not in contact (interference) with the first driven shaft 12, and the contact between the second protrusion portion 36b of the first drive part 36 and the first driven shaft 12 of the substrate holder 11 is released, and also, it becomes possible to move the substrate holder 11 in the second conveying direction P2 without bringing the second protrusion portion 36b of the first drive part 36 into contact with the second driven shaft 13 of the substrate holder 11.

According to the present embodiment as discussed above, by providing the third tapered portion 36e formed such that the tip portion of the second protrusion portion 36b on the upstream side in the conveying direction is inclined inward in the conveying direction at the tip portion of the second protrusion portion 36b of the first drive part 36 which is moved by the conveying drive member 33, it is possible to shorten the movement distance during the operation of releasing the contact between the first drive part 36 and the first driven shaft 12, and shorten the operation time in comparison with the prior art having no third tapered portion 36e, thereby greatly accelerating the timing of delivering the substrate holder 11 to the substrate carrying-in/out mechanism 6.

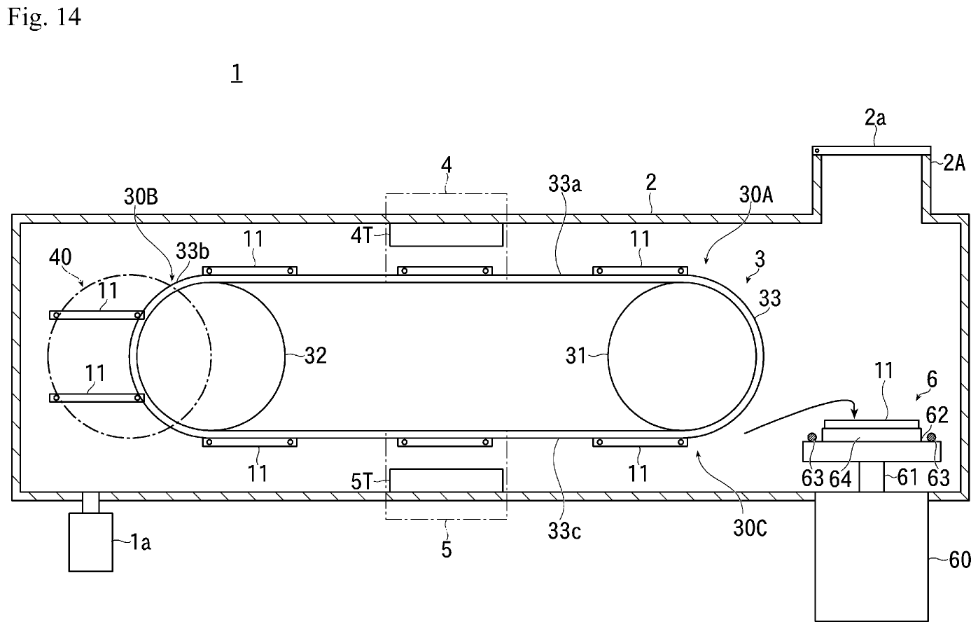

After the above-discussed operation is performed, the substrate holder 11 is moved in the second conveying direction P2 by the transfer robot 64 of the substrate carrying-in/out mechanism 6 shown in FIG. 14 so as to separate from the first drive part 36.

Further, taking out operation of the substrate holder 11 is performed by using the transfer robot 64 of the substrate carrying-in/out mechanism 6, and the substrate holder 11 and the transfer robot 64 are arranged on the supporting part 62 as shown in FIG. 14.

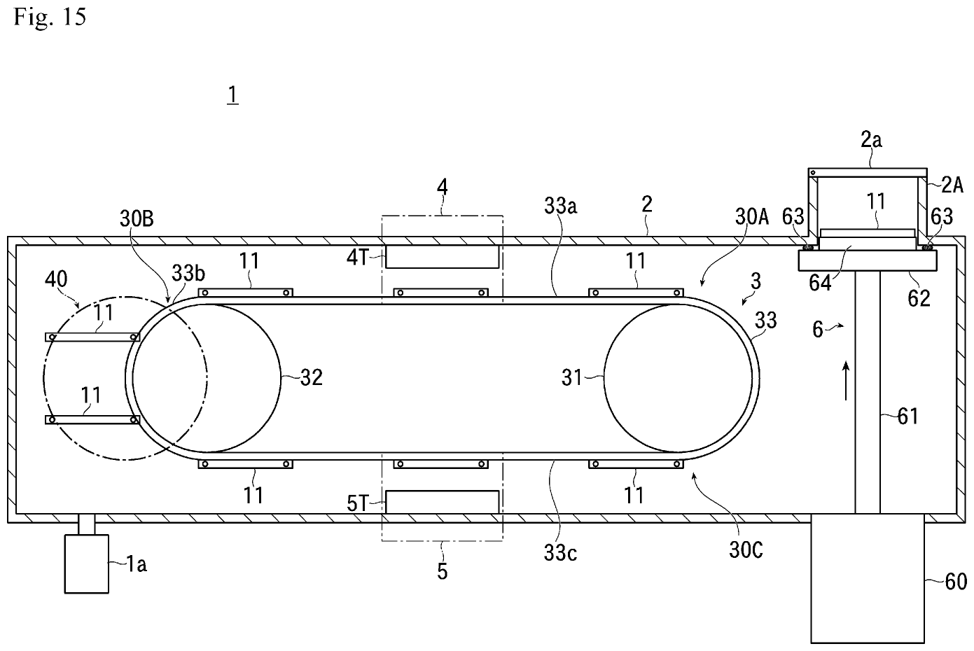

Thereafter, as shown in FIG. 15, the supporting part 62 of the substrate carrying-in/out mechanism 6 is raised, and the seal member 63 on the supporting part 62 is brought into tight contact with the inner wall of the vacuum chamber 2 so that venting is performed to the atmospheric pressure in a state where the environment in the carrying-in/out chamber 2A is isolated from the environment in the vacuum chamber 2.

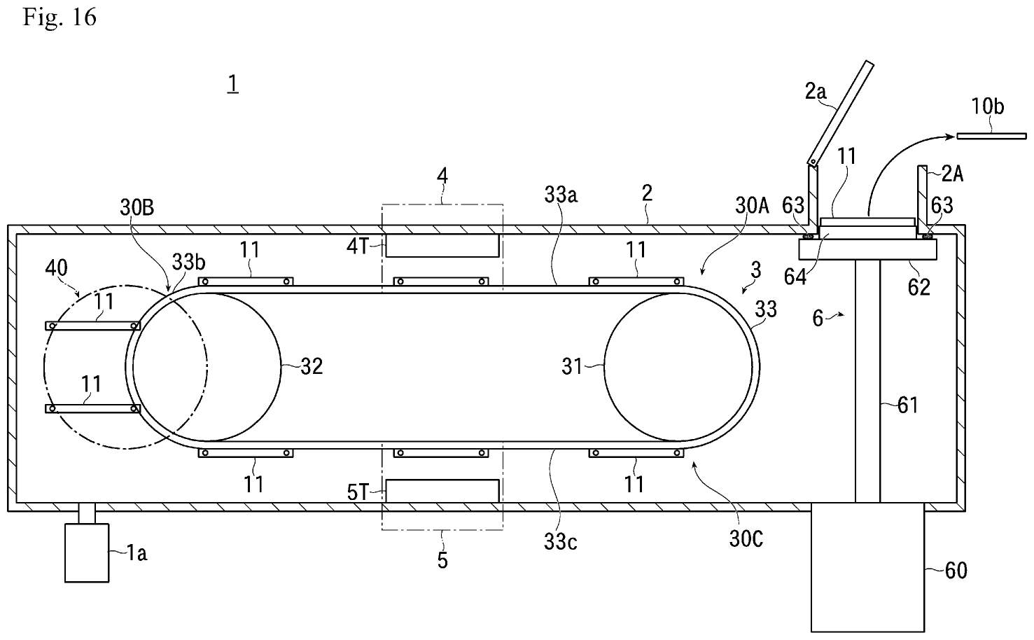

Then, as shown in FIG. 16, the lid part 2a of the substrate carrying-in/out chamber 2A is opened, and the processed substrate 10b is taken out from the substrate holder 11 into the air atmosphere by using a transfer robot (not shown).

Thereafter, returning to the state shown in FIG. 6, by repeating the above-discussed operation, the above-discussed vacuum processing is performed on both surfaces of each of the plurality of substrates 10.

In the present embodiment discussed above, because in the vacuum chamber 2 where a single vacuum atmosphere is formed, the conveying path is formed so that the projection shape with respect to the vertical plane is a continuous ring shape, and the substrate holder conveying mechanism 3 for conveying a plurality of substrate holders 11 along the conveying path is provided, the space occupied by the conveying path can be greatly reduced as compared with the conventional art, and thereby, a large space saving of the apparatus can be achieved, so that it is possible to provide a compact vacuum processing apparatus having a simple configuration.

In addition, in the present embodiment, it is configured such that the forward-path side conveying part 33a of the conveying drive member 33 that conveys the introduced substrate holder 11 in the horizontal state along the conveying path in the first conveying direction P1 passes through the first processing region 4, and the return-path side conveying part 33c of the conveying drive member 33 that conveys and discharges the substrate holder 11 in the horizontal state along the conveying path in the second conveying direction P2 opposite to the first conveying direction P1 passes through the second processing region 5. Furthermore, it is configured such that the first drive part 36 of the substrate holder conveying mechanism 3 and the second drive part 46 of the direction changing mechanism 40 are made to operate in synchronization with each other, the first and second driven shafts 12 and 13 of the substrate holder 11 are guided and conveyed along the first and second direction changing paths 51 and 52 of the direction changing mechanism 40, respectively, and thus, the substrate holder 11 is delivered from the forward-path side conveying part 33a of the conveying drive member 33 to the return-path side conveying part 33c while the relationship between upper and lower portions of substrate holder 11 is maintained. According to the present embodiment having such a configuration, it is possible to provide a passage type vacuum processing apparatus capable of efficiently processing both surfaces of the substrate 10.

Further, in the present embodiment, because the substrate holder 11 is configured to hold a plurality of substrates 10 arranged apposed in a direction orthogonal to the conveying direction, the length of the substrate holder and the surplus space due to the length can be reduced as compared with the case where the substrate holder holding a plurality of substrates arranged side by side along the conveying direction is conveyed and processed, and thus further space saving of the vacuum processing apparatus can be achieved.

It should be noted that the present disclosure is not limited to the above-discussed embodiment, and various modifications can be made.

For example, in the above-discussed embodiment, the upper portion of the conveying drive member 33 is defined as the forward-path side conveying part 33a that is the first conveying part, and the lower portion of the conveying drive member 33 is defined as the return-path side conveying part 33c that is the second conveying part, but the present disclosure is not limited to this, and the relationship between the upper and lower portions of the substrate holder 11 may be reversed.

In the above embodiment, each of the substrate holder conveying mechanism 3 and the direction changing mechanism 40 is constituted by a pair of sprockets and a chain wound around the pair of sprockets. However, it is also possible to use a ring-shaped conveying drive mechanism using, for example, a belt or a rail.

Furtherover, the substrate holder supporting mechanism 18 may be formed by using a belt or a rail instead of a roller.

On the other hand, the direction changing mechanism 40 is not limited to the above-discussed embodiment constituted by the above-discussed first to third guide members 41 to 43, and can be modified as follows.

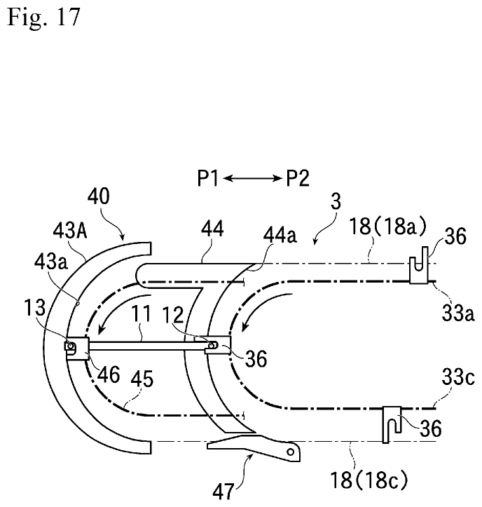

For example, in the modified example shown in FIG. 17, a guide member 44 corresponding to the second guide member 42 and a guide member 43A corresponding to the third guide member 43 are provided, and it is configured such that the first and second direction changing paths are formed by the pair of guide members 44 and 43A.

Here, the guide member 44 is formed, for example, like hiragana “Te” (shape similar to T), and a portion 44a thereof on the upstream side in the first conveying direction P1 is formed in a curved surface shape equivalent to the portion of the second guide member 42 on the upstream side in the first conveying direction P1.

Then, it is configured such that the first driven shaft 12 of the substrate holder 11, which is driven by the above-discussed first drive part 36, is brought into contact with a portion 44a of the guide member 44 on the upstream side in the first conveying direction P1 so as to guide the substrate holder 11 along the portion 44a from the upper side to the lower side.

On the other hand, the portion 43a of the guide member 43A on the upstream side in the first conveying direction P1 is formed in a curved surface shape equivalent to the portion of the third guide member 43 on the upstream side in the first conveying direction P1.

Then, it is configured such that the second driven shaft 13 of the substrate holder 11, which is driven by the above-discussed second drive part 46, is brought into contact with a portion 43a of the guide member 43A on the upstream side in the first conveying direction P1 so as to guide the substrate holder 11 along the portion 43a from the upper side to the lower side.

According to this example having such a configuration, the above-discussed first guide member 41 is unnecessary, and the material of the guide member 44 corresponding to the second guide member 42 can be reduced, so that it is possible to simplify the configuration of the direction changing mechanism 40, and further simplify the apparatus configuration and reduce the cost.

The shapes of the first and second drive parts 36 and 46 are not limited to those of the above-discussed embodiment, and various shapes can be adopted as long as the first and second drive parts 36 and 46 can be reliably brought into contact with the first and second driven shafts 12 and 13 of the substrate holder 11, and support and drive them.

Furthermore, in the above embodiment, as processing in a vacuum, an apparatus that performs sputtering has been discussed as an example. However, the present disclosure is not limited thereto and can be applied to a vacuum processing apparatus that performs various processing such as, for example, plasma processing, ion implantation processing, vapor deposition processing, chemical vapor deposition processing, focused ion beam processing, etching processing and the like.

In this case, the first and second processing regions 4 and 5 may be provided with processing sources for performing different processing.

Furthermore, the present disclosure can be applied not only to the case where the substrate 10a before processing is carried into the vacuum chamber 2, and the processed substrate 10b is carried out from the vacuum chamber 2 as in the above embodiment, but also to the case where the substrate 10a before processing is carried into the vacuum chamber 2 together with the substrate holder 11, and the processed substrate 10b is carried out from the vacuum chamber 2 together with the substrate holder 11.

1. A vacuum processing apparatus, comprising:
a vacuum chamber in which a single vacuum environment is formed;
first and a second processing regions provided in the vacuum chamber for performing predetermined vacuum processing on a substrate held by a substrate holder of a plurality of substrate holders;
a conveying path for conveying the substrate holder, the conveying path being formed such that a projection shape with respect to a vertical plane forms a continuous ring shape; and
a substrate holder conveying mechanism configured to convey the plurality of substrate holders each having a first and a second driven part along the conveying path,
wherein the conveying path includes:
a first conveying part that conveys the substrate holder in a horizontal state along the conveying path in a first conveying direction;
a second conveying part that conveys the substrate holder in a horizontal state along the conveying path in a second conveying direction opposite to the first conveying direction and discharges the substrate holder;
a conveying and reversing part that reverses and conveys the substrate holder from the first conveying part toward the second conveying part, and
the conveying path is configured such that the first conveying part passes through one of the first and second processing regions, and the second conveying part passes through the other of the first and second processing regions,
wherein the substrate holder conveying mechanism includes a plurality of first drive parts each being in contact with the first driven part of the substrate holder, and driving the substrate holder along the conveying path,
wherein a direction changing mechanism is provided in a vicinity of the conveying and reversing part of the conveying path, that includes a plurality of second drive parts each being in contact with the second driven part of the substrate holder and driving the substrate holder in the first and second conveying directions, and first and a second direction changing paths for respectively guiding and conveying the first and second driven parts of the substrate holder so as to change a direction of the substrate holder from the first conveying direction to the second conveying direction, and
wherein the conveying path is configured such that the first drive parts of the substrate holder conveying mechanism and the second drive parts of the direction changing mechanism are made to operate in synchronization with each other, and the first and second driven parts of the substrate holder are respectively guided and conveyed along the first and second direction changing paths of the direction changing mechanism, and thereby, the substrate holder is delivered from the first conveying part to the second conveying part of the conveying path while a relationship between upper and lower portions of the substrate holder is maintained.

2. The vacuum processing apparatus according to claim 1, wherein each of the first direction changing path and the second direction changing path is formed in an equivalent curved shape that is convex toward the first conveying direction.

3. The vacuum processing apparatus according to claim 2, wherein each of the first direction changing path and the second direction changing path is provided by arranging a pair of guide members close to each other so as to be opposed to each other with a gap slightly larger than a diameter of a first driven part of the substrate holder.

4. The vacuum processing apparatus according to claim 1, wherein the first and second driven parts of the substrate holder are provided so as to extend in a direction orthogonal to the first and second conveying directions, and lengths of the first and second driven parts are different from each other.

5. The vacuum processing apparatus according to claim 1, wherein the direction changing mechanism is disposed at a position outside the substrate holder conveying mechanism with respect to the first and second conveying directions.

6. The vacuum processing apparatus according to claim 1, wherein in the first and second processing regions, film formation is performed in a vacuum environment.

7. The vacuum processing apparatus according to claim 1, wherein the substrate holder is configured to hold a plurality of substrates to be film formed apposed in a direction orthogonal to the first and second conveying directions.
